(19) United States
(12) Patent Application Publication
(10) Pub. No.: US 2013/0339814 A1
(43) Pub. Date: Dec. 19, 2013

(54) Method for Processing Messages for Outsourced Storage and Outsourced Computation by Untrusted Third Parties

(71) Applicants: Shantanu Rane, Cambridge, MA (US); Wei Sun, Kitchener (CA)

(72) Inventors: Shantanu Rane, Cambridge, MA (US); Wei Sun, Kitchener (CA)

(21) Appl. No.: 13/525,209

(22) Filed: Jun. 15, 2012

(51) Int. Cl. H03M 13/05; G06F 11/10

(52) U.S. Cl. 714/752; 714/E11.032

(57) ABSTRACT

A message is stored and processed by an untrusted third party by generating a codeword using a selected one of a set of error correcting codes (ECC). The selected ECC depends on a weight rate of the block, and each codeword satisfies a minimum distance criterion with respect to the codewords of all possible ECCs and all possible weight rates. Each symbol of the codeword is modifying explicitly, randomly and independently according to parameters of a channel to obtain a randomized codeword. Then, an encoded result of an operation performed on the randomized codeword by the untrusted third party is decoded.

### FIELD OF THE INVENTION

This invention relates generally to outsourcing data in messages, and more particularly to processing data in messages by entrusted third parties without revealing the data.

### BACKGROUND OF THE INVENTION

Outsourcing Data

When data are outsourced by a client to a server, it is often desirable to “hide” the data from the server in a secure manner, particular if the server is an untrusted third party. The reason for this is to preserve privacy of client information, and to prevent the server from gaining access to sensitive information about processes used to acquire and generate the data. For these reasons, the data are often modified in a secure manner before outsourcing to the server.

There are several reasons why such outsourcing is necessary. For example, the client acquires or generates a large volume of data, much larger than the client can efficiently store in a cost effective manner. This would be the case where the client is a small form factor device, such as a mobile handheld device.

In addition, processing all of the data can be burdensome or impossible for the client. In addition, the client may not be capable of performing complex processing tasks as found in many computer applications. It is assumed the server has effectively unlimited memory and computational resources available for the client at a reasonable cost.

Therefore, the client transfers the data to the server for storage, and the server performs processing computation on the data, such as computing averages, variances or other aggregate statistics. In a second example, the client needs to make the data available to an untrusted third party to perform aggregate computations for the purposes of research, monitoring, etc.

Because of the privacy concerns, the client does not want to provide the data to the server in raw form. In addition, the client may be interested in periodically retrieving portions of the data from the server, for example, to conduct an audit on the data.

Therefore, it is desired to provide secure methods to accomplish the above competing goals, i.e., for the server to aggregate statistics, while keeping the client's data private, and also to allow the client exactly retrieve portions of the data whenever required.

Cloud Computing

The advent of “cloud” computing has caused a fundamental change in the way individuals and businesses perform tasks such as computational processing and archival of data to address the above goals.

In particular, instead of investing in expensive hardware to perform computationally intensive tasks, or continuously buying memory to satisfy rapidly growing archives of data, it has become convenient, and in some cases, economically indispensible to shift these activities to the cloud.

The definition, scope and capabilities of cloud computing have widened considerably with time, and continues to change. The focus here is one aspect, i.e., that of outsourcing data.

For example, the client is operated by an entitity that wants access to a large storage facility, e.g., at the server, to store a continuously growing archive of data. Examples of such an archive include a history of login successes or failures at all of the computers and peripherals at the client facility. The data can be a history of medical records of patients in the client's medical facility, or a record of voting patterns, and so on.

The server provides the cloud-based storage service for the client. In addition to storage, the client desires that the server also provides a limited amount of processing capability, such as determining some agreage statistic over the data. For example, at the end of every day, the server provides the client the percentage of failed logins for all the peripherals at the client facility. Furthermore, the client should be able to retrieve portions of the data in exact form for auditing purposes.

With a trusted third party, this is trivial to do. However, the goal is to performing the above tasks, i.e., storage and processing, under privacy constraints. These constraints dictate that the server should be able to determine the aggregate statistics on all the data, without knowing individual instances of the data. Similarly, the server should be able to audit the data, without knowing what the data represents.

One solution to prevent the server from discovering the data is to use symmetric key encryption via block ciphers or stream ciphers. In that solution, the client encrypts the data before transmitting the data to the server for processing and storage. However, because encryption hides the structure of the data, that method makes it impossible for the server to provide meaningful results after processing the data.

In an alternative solution, the client uses a homomorphic encryption to encrypt the data before transmitting the data to the server. Utilizing the properties of additively or multiplicatively homomorphic cryptosystems, the server can determine encrypted value of some simple aggregate functions on the data, e.g., an average value, and transmit the statistics to the client.

That solution facilitates computational privacy, oblivious computation as well as perfect data retrieval. However, it has sever drawbacks. Homomorphic encryption systems are public key cryptosystems, so the ciphertext is much larger than the plaintext, resulting in vastly larger storage requirements at the server and a prohibitive overhead in communicating the data to the server, as well as increased processing complexity.

A simpler and less complex solution to the above problem is to add noise to the client data before the data are transmitted to server. That method effectively hides the individual data instances, while still allowing aggregate statistics to be determined on the data, and is similar to conventional randomized response survey techniques. However, data retrieval is not straightforward, unless the client can reproduce the noise sequence exactly. Of course, storing the noise sequence is not an option because if the client had enough memory to store the noise sequence, the client would have no need to outsource.

Random Number Generation

One information theoretically secure way to hide the data adds random values drawn from a probability distribution. For numeric data, for example, privacy can be obtained by masking the data using numbers sampled from a uniform distribution. The numbers can be sampled using a Cryptographically Secure Pseudorandom Number Generator (CS-PRNG). The CS-PRNG uses a seed to generate a pseudorandom sequence of bits, which, in turn, can be used to generate numbers from a desired probability distribution. Typically, the numbers are integers.

Aggregate Statistics

Even though the data are hidden from the server, it is often beneficial to enable the server to determine aggregate statistics that provide summary information about portions of the data. For example, it can be desired to determine a number of pages printed on a given printer on a given day. As another example, it can be desired to determine a total number of transactions that are performed by a trader during a given time interval.

Common aggregate statistics include sum, weighted sum, average, weighted average, higher moments, weighted higher moments, etc. Techniques such as randomized response hides individual data but allow determination of estimates of aggregate statistics on the data. Randomized response is a method that allows respondents to respond to sensitive data while maintaining confidentiality.

Audits

From time to time, the client may want to conduct audits on portions of the data stored at the server. An audit refers to recovering a portion of the stored data, and verifying its integrity or correctness according to metrics determined by the client. To perform the audit, the client can request some of the modified data from the server at any time. To be able to access the unmodified data, any method used to randomize the data should be perfectly reversible.

### SUMMARY OF THE INVENTION

The embodiments of the invention provide a method for processing data in messages generated by an untrusted third party server. The server can determine aggregate statistics on the data, and the client can retrieve the outsourced data exactly. In the process, individual entries in the database are not revealed to the server because the data are encoded. The method uses a novel combination of error correcting codes (ECC), and a randomization response, which enables responses to sensitive while maintaining confidentiality of the responses.

Parameters for constant weight rate codes are designed such that the probability of erroneous decoding is negligible. The embodiments use the constant weight rate error correcting codes, in conjunction with conventional randomized response. In particular, given the distribution of the client data, and the randomization parameters, the client can obtain aggregate statistics from the server, and derive the rate of the error correcting code required so that the client can retrieve instances of data from the server with a negligible probability of error.

### BRIEF DESCRIPTION OF THE DRAWINGS

FIG. 1A is a block diagram of a method and system for processing data in a client message by an untrusted third party server according to embodiments of the invention;

FIG. 1B is a block diagram of the method for encoding and decoding the message according to embodiments of the invention;

FIG. 2 is a block diagram of a method for aggregating statistics on the message according to embodiments of the invention; and

FIG. 3 is a block diagram for auditing client data according to embodiments of the invention.

### DETAILED DESCRIPTION OF THE PREFERRED EMBODIMENTS

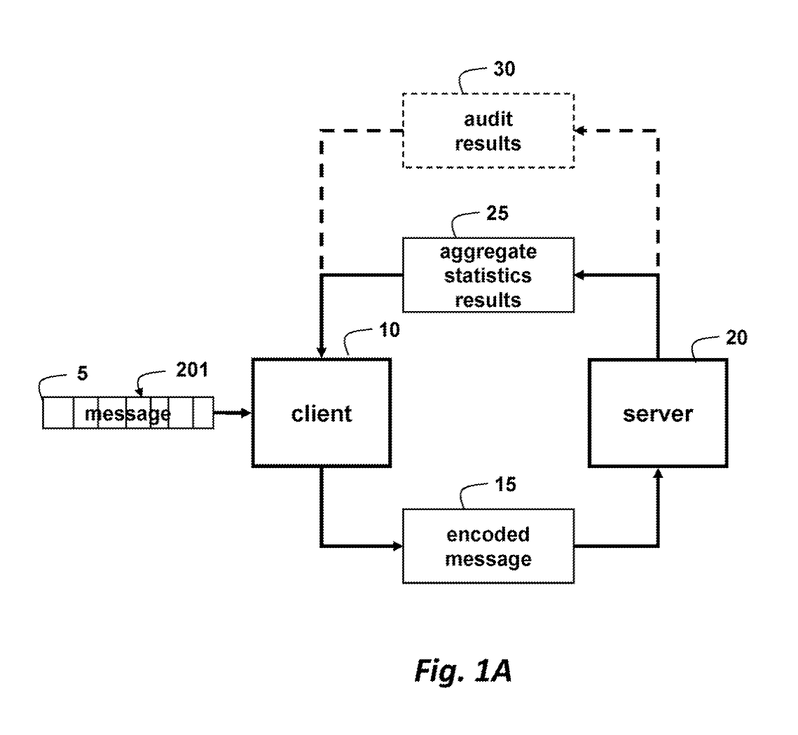

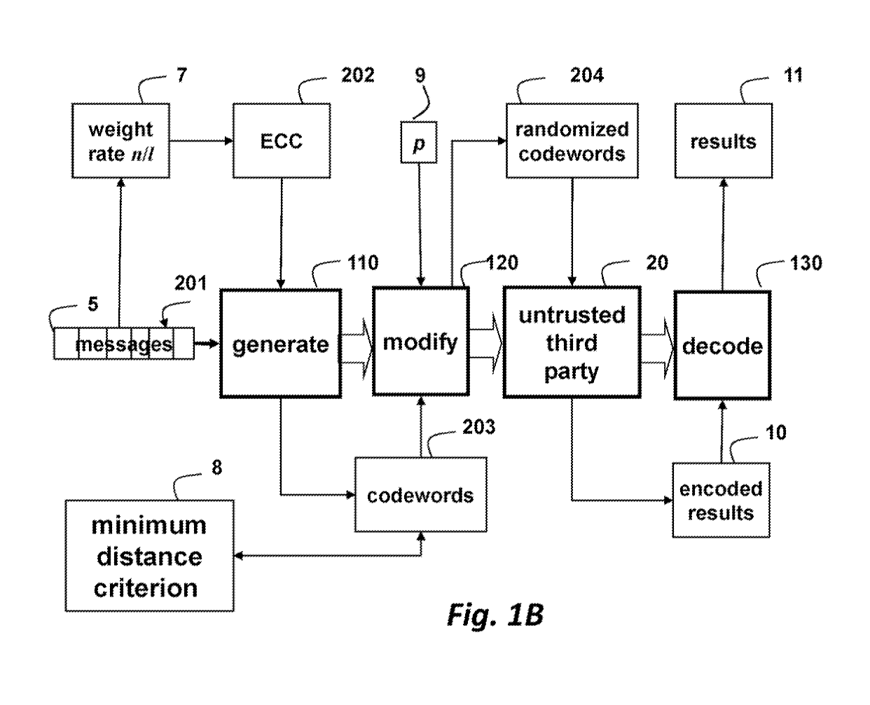

As shown in FIG. 1A, embodiments of our invention provide a method and system for processing blocks 201 of a message 5 generated by a client 10 by an untrusted third party server 20 without revealing the underlying content of the data in the message. The encoded message 15 has the property that aggregate statistics 25 on the data can be determined by the server. Alternative, the server can audit the stored messages, and provide audit results 30 to the client. The client and server each have one or more processors, memory, and input/output interfaces as known in the art. The processors implement the methods described herein.

FIG. 1B shows the general method for encoding and decoding the blocks of the message 105 of length/processed by the untrusted server using a set of error correcting codes (ECC) 202, wherein the ECC for a particular block depends on a weight rate 7 of the block, and wherein each codeword satisfies a minimum distance criterion 8 with respect to the codewords of all possible ECCs and all possible weight rates. Each symbol in the codeword is modified 120 explicitly, randomly and independently according to parameters 9 of a communication channel to obtain a randomized codeword 204. An encoded result 10 of an operation performed on the randomized codeword by the server is decoded 130 by the client to obtain the result 11.

Problem Formulation

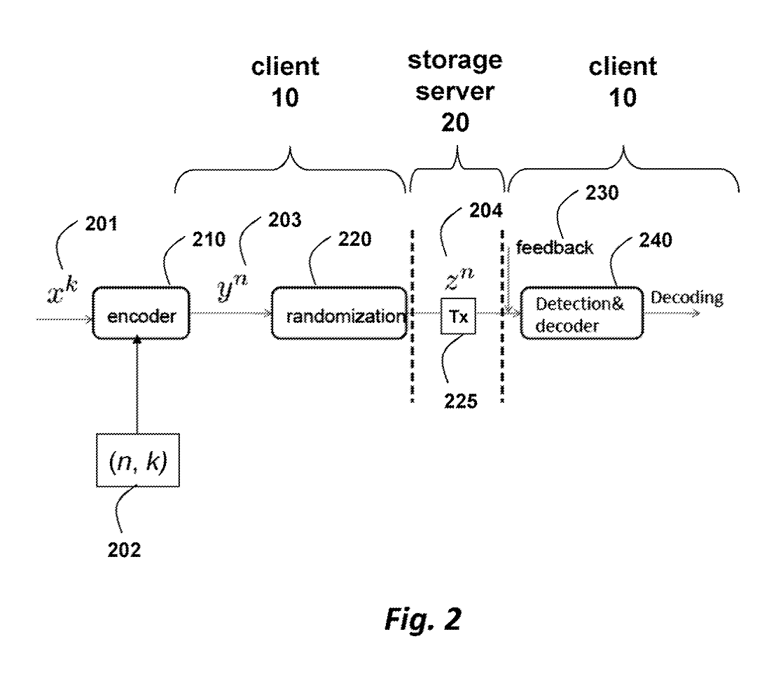

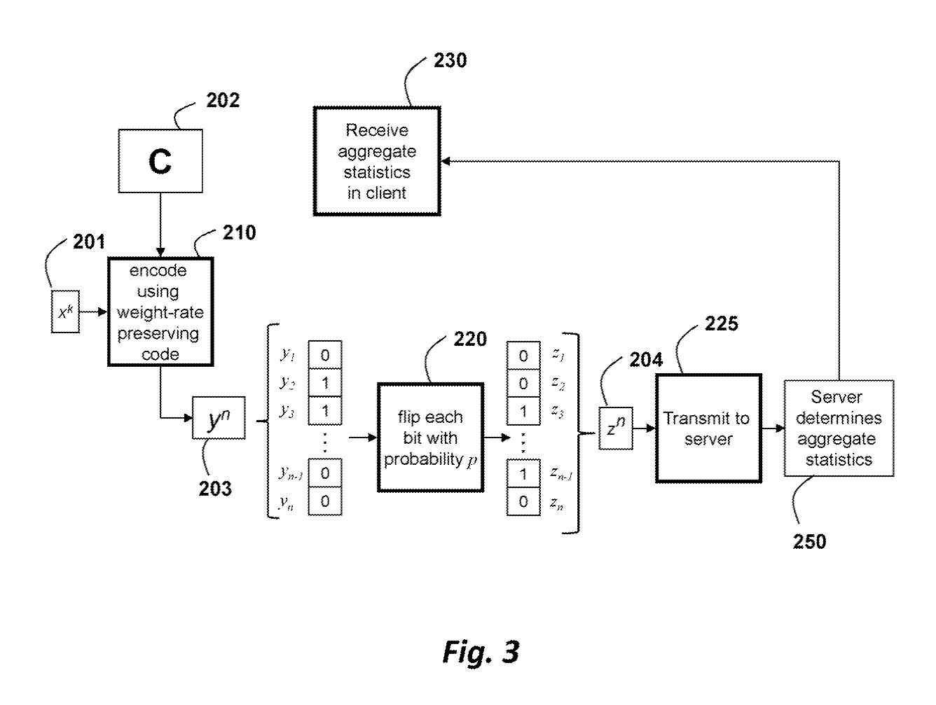

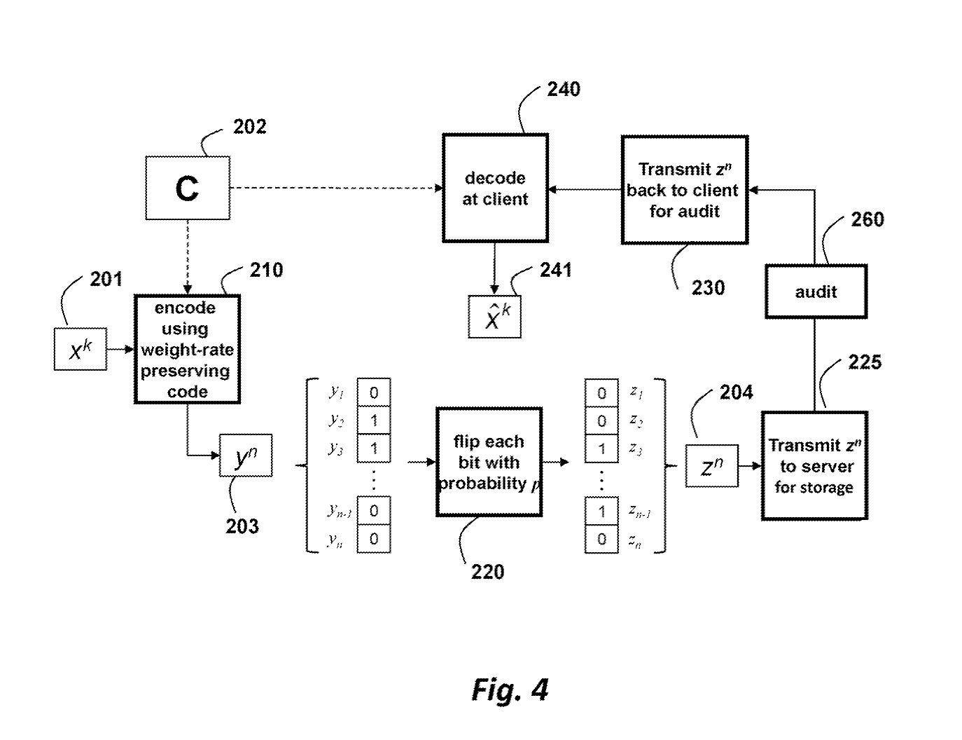

FIG. 2 shows a system and method for encoding a message according to embodiments of the invention.

Consider a block x^{k}=(x₁, x₂, . . . , xₖ) ∈ {0,1} 201 of the message 5, which is in a form of a binary vector. The client encodes 210 the binary vector with an error correcting code (ECC) (n, k) 202, and generates a codeword yⁿ 203, the codeword can be in the form of binary values or symbols. The encoding is performed using a weight rate preserving error correcting code.

Weight rate preserving codes have been used in communication networks. In communication system, the prior art minimum distance criterion only satisfies a specific ECC code and weight rate used in the design of the code.

In contrast, we do not use the ECC in a communication application, instead we use the ECC to provide security for data processed by untrusted third parties. In addition, we have a family (set of) error correcting code, and each codeword satisfies a minimum distance criterion not just with respect to codewords of a single ECC, but with respect to the codewords of all possible ECCs and all possible weight rates. This is a novel design and use of our error correcting codes. Specifically, by using the weight rate preserving ECCs prior to performing the random inversion, enables the client to recover the results.

For reasons of security and privacy, the client randomizes 220 the codeword yⁿ according to a parameter of a hypothetical noisy channel, and transmits the randomized codeword zⁿ 204 to the server. The randomization is done by randomly inverting (flipping) each symbol in the codeword with a crossover probability p. The crossover probability is obtained for a design of the hypothetical noisy channel. Because, the channel is designed for or by a specific client, other entities, included the server, cannot know this parameter.

The hypothetical noisy channel can be generated in a variety of ways. One way to generate the channel is to use a cryptographically secure pseudo random number generator (CS-PRNG) to determine whether to flip the bit (symbol) or not. This noise process can be regenerated if desired later using the same seed.

Another method is to use a physical noise process, called a physical unclonable function (PUF) to decide whether to flip the bit or not. The PUF is an embodied of a physical channel that can be evaluates but not predicted. In this respect, the PUF is an analog of a one-way function. With the PUF, the noise process cannot be regenerated. This is not a problem for the invention, because, whatever the noise process, the ECC enables the client to recover the noise-free codeword, and hence the message, given the noisy codeword.

The server stores the randomized codeword, i.e., the vector zⁿ, and feeds back 230 some results about zⁿ (or the entire vector zⁿ) to the client after processing, e.g., aggregate statistics on the message, and audit results of previous messages received by the server.

If the client wants to conduct an audit, then the client requests the vector zⁿ from the server, and decodes 240 the vector to determine the vector k^{k} 241.

Definition 1

Let (n, k) be a binary code C of 2^{k} codewords. Let f be a one-to-one encoding function from a vector space M={0,1}^{k} to C, define a difference between the vector x^{k} and its corresponding codeword yₖ, as:

$$Δ ( C , f ) = {max}_{{x}^{k} ∈ {\{ 0 , 1 \}}^{k}} \vert \frac{wt ( {x}^{k} )}{k} - \frac{wt ( f ( {x}^{k} ) )}{n} \vert ,$$

where wt(x^{k} i)is the weight of x^{k}. The code C is called weight rate Δ(C)-preserving if Δ(C)=min_{f}Δ(C, f). Particularly, if Δ(C)=0, then the code C is called weight rate preserving. The weight rate for a binary codeword can be the number of symbols with the value one (1) in the codeword divided by a length of the codeword (in symbols, e.g., bits).

The quantity Δ(C) describes a difference between the weight rate of the vector x^{k} and that of its corresponding codeword yₖ, in the term of the weight rate. This quantity is a measure of how much statistical information of the vector is preserved in the corresponding codeword. Thus, Δ(C)=0 implies that if 20% of the symbols in x^{k} have a value 1, for example, this can correspond to the percentage of unsuccessful logins at a particular computer terminal, then 20% of the binary symbols in the codeword also have value 1.

if the code C is weight rate preserving, then there exists an encoding method such that the weight rate is preserved exactly, that is,

$$\frac{wt ( {x}^{k} )}{k} = \frac{wt ( f ( {x}^{k} ) )}{n} .$$

Particularly, if C is a linear ECC [n, k], then

$$Δ ( C ) = {min}_{G} {max}_{{x}^{k} ∈ {\{ 0 , 1 \}}^{k}} \vert \frac{wt ( {x}^{k} )}{k} - \frac{wt ( {x}^{k} G )}{n} \vert ,$$

where G is a generator matrix of the linear code C, and min and max refer to the minimum and maximum functions.

For simplicity of encoding, decoding and storage efficiency, the weight rate preserving linear ECC is used in our preferred embodiment. However, the invention also covers ECC designs in which the weight rate is not exactly preserved. In this case, the quantity Δ(C) is not exactly 0. Relaxing the requirement on Δ(C) may allow more efficient code designs, i.e., designs that allow a smaller value of codeword length n to be used.

For reasons of security and privacy, the server only determines some aggregate statistical result about the vector transmitted, such as the number of binary events accumulated over an entire day. The server feeds back 230 the result to the client. The server cannot invert the ECC because, in this embodiment, the server does not know the mapping between the input message x^{k} and the output randomized codeword. This mapping from messages to codewords is non-linear, and may indeed be randomized using a CS-PRNG, wherein the state information of the CS-PRNG is known only to the client.

Given the weight rate preserving codeword, the server can determine the exact aggregate statistics on the codeword. To prevent the server from learning the exact aggregate statistic, but to enable the server to obtain an estimate of the aggregate statistic, the client randomizes each symbol of the codeword with the crossover probability p before transmitting the codeword to the server, as shown in FIG. 2. This technique of randomization is called a randomized response, where confidentiality of sensitive data is maintained.

Definition 2

Let 0≦p≦1. Randomized response is a binary symmetric channel with the crossover probability p, that is,

Pr{Z=1|Y=0}=Pr{Z=0|Y=1}=p,

where Y is an input symbol, Z is an output symbol. Generally, if a binary vector y with length n is randomized with the crossover probability p, then the weight rate

$$\frac{wt ( y )}{n}$$

of y can be estimated unbiasedly from the output binary vector z, given p. That is,

$$\frac{wt ( y )}{n} = \frac{p + \frac{wt ( z )}{n}}{1 - 2 p} ,$$

and a variance of this estimation is

$$\frac{p ( 1 - p )}{n ( 1 - 2 p )} + \frac{wt ( y ) ( n - wt ( y ) )}{{n}^{3}} .$$

For a large length n of the codeword, this estimate can be very accurate. In some embodiments, it is not desired for the server to know the exact aggregate statistics, so the parameter p is controlled by the client and not revealed to the server. In this embodiment, the server cannot determine whether a change in the aggregate statistic is due to a change in the statistical properties of the input message x^{k}, or if it is because of a change in the crossover probability parameter of the randomizing channel.

In other embodiments, if revealing the exact aggregate statistic to the server is not a problem, then the parameter p may be revealed to the server.

The principle used for randomizing is to pass the codeword through a hypothetical noisy channel, where the parameters used to encode the message into the codeword, such as the minimum distance, are selected based on the parameters, such as the crossover probability p of the noisy channel.

If the weight rate preserving code is used for encoding, then, after receiving a report about the weight wt(z) from the server, the client can accurately estimate the weight rate of the original message (the vector x^{k}). The client can then determine whether or not to decode the vector based on the quality of the vector.

Definition 3

A weight rate preserving (n,k)-code C is called ε-admissible, with respect to the crossover probability p, if there exist an encoding E and a decoding D such that the average probability of erroneous decoding over all codewords is less than ε, that is,

$${P}_{e} = \frac{1}{{2}^{k}} {\sum }_{x ∈ M} Pr \{ {E}^{- 1} ( D ( z ) ) \dot{\neq } x \vert x \} \leq ɛ ,$$

where E⁻¹ is the inverse mapping of the encoding E from the code to the vector space M, and z is the randomized output with the crossover probability p of the input codeword E(x) of the vector x.

For storage efficiency and coding simplicity, the crossover probability p of the binary symmetric channel and the allowed average probability of erroneous decoding ε for a vector length of k symbols (bits), we are interested in the coding rate defined by

$$R = \frac{k}{n} .$$

Theorem 1

For given vector length k, crossover probability p of the randomized response and the allowed average probability of erroneous decoding ε, define for each i=0, 1, . . . , k,

$${d}_{i} = \frac{log \frac{2 ( \begin{matrix}k \\ i\end{matrix} )}{ɛ}}{D ( \frac{1}{2} \vert \vert p )} , \\ and$$

$$\overline{d} = \frac{k + log \frac{2}{ɛ}}{D ( \frac{1}{2} \vert \vert p )} .$$

Then, there exists an ε-admissible weight rate preserving code C with

$$rate R \leq \frac{1}{{δ}^{*}} , \\ where$$

$${δ}^{*} = max \{ {δ}_{0} , {δ}_{1} , … , {δ}_{k} , \overline{d} \} ,$$

and δᵢ is the unique solution of the equation

$$\frac{{( k δ )}^{i δ - {d}_{i} / 2 + 1}}{( i δ ) !} = ( \begin{matrix}k \\ i\end{matrix} ) .$$

The proof for the above is given in the Appendix.

A better decoding for constant weight codes can increase the performance in terms of average probability of decoding, for example, for a geometric approach for decoding constant weight codes by embedding. For simplicity, we use the universal MMD.

### Effect of the Invention

The embodiments of the invention provide a novel approach to address the problem of secure outsourcing at a in a message for processing, such as determining aggregate statistics from a client to a server, such that the server learns little or no information about the data in the message, while the client can detect the quality of vectors from the server and is able to decode these vectors correctly with high probability if vectors are needed to be recovered from the server.

Although the invention has been described by way of examples of preferred embodiments, it is to be understood that various other adaptations and modifications can be made within the spirit and scope of the invention. Therefore, it is the object of the appended claims to cover all such variations and modifications as come within the true spirit and scope of the invention.

Appendix

Proof

Given the vector length k, and the crossover probability p of the randomized response, we prove constructively that the code rate 1/δ is achievable. That is, we can construct a weight rate preserving block code, such that the average probability of erroneous decoding is less that the arbitrary but fixed ε>0.

Codebook Generation

For each i=0, 1, . . . , k, construct a constant weight code Cᵢ with length kδ, weight iδ and minimum distance dᵢ, where

$${d}_{i} = \frac{log \frac{2 ( \begin{matrix}k \\ i\end{matrix} )}{ɛ}}{D ( \frac{1}{2} \vert \vert p )} .$$

Then,the codebook is expressed as

C=∪ᵢ₌₀^{k}Cᵢ.

Encoding

For a vector x with weight i, assign a codeword from the constant weight code Cᵢ. The weight rate

$$\frac{i}{k}$$

of a vector x is preserved in its codeword for each i=0, 1, . . . , k.

Decoding

After receiving the vector z from the randomized response with crossover probability p, a decoder based at the client, can use Minimum Distance Decoding (MDD) to determine a codeword y₀ ∈ C such that

$$dist ( z , {y}_{0} ) = {min}_{y ∈ C} dist ( z , y ) ,$$

and then the decoded codeword is y₀.

Existence of Codes

Define for each i=0, 1, . . . , k.

$${f}_{i} ( x ) = \frac{{( kx )}^{ix - {d}_{i} / 2 + 1}}{( ix ) !} .$$

It can be shown that ƒᵢ(x) is an increasing function of x.

By the definition of δ, δ≧δᵢ. Thus, from the definition of δᵢ

$${f}_{i} ( δ ) \geq {f}_{i} ( {δ}_{i} ) \geq ( \begin{matrix}k \\ i\end{matrix} ) ,$$

which is the lumber of the codewords in Cᵢ. That is,

$$\frac{{( k δ )}^{i δ - {d}_{i} / 2 + 1}}{( i δ ) !} \geq ( \begin{matrix}k \\ i\end{matrix} ) .$$

From a well-known result of constant weight codes, there exists a constant weight code with length kδ, weight iδ and minimum distance dᵢ if

$$\frac{{( k δ )}^{i δ - {d}_{i} / 2 + 1}}{( i δ ) !} \geq ( \begin{matrix}k \\ i\end{matrix} ) .$$

Average Probability of Erroneous Decoding

A codeword y ∈ Cᵢ is randomized and a vector is received. Then, there are two kinds of events of erroneous decoding:
E₁: A codeword y′ ∈ Cᵢ is decoded, but y′≠y; and
E₂: A codeword from Cⱼ is decoded, j≠i.

In the following, we describe that the average probability of erroneous decoding over all codewords of C is less than ε. We have

$$\begin{matrix}{P}_{e} = \frac{1}{{2}^{k}} {\sum }_{i = 0}^{k} {\sum }_{y ∈ {C}_{i}} Pr \{ Decoding of z is not equal to y \vert y is randomized \} \\ = \frac{1}{{2}^{k}} {\sum }_{i = 0}^{k} {\sum }_{y ∈ {C}_{i}} ( Pr \{ {E}_{1} \vert y is randomized \} + Pr \{ {E}_{2} \vert y is randomized \} ) .\end{matrix}$$

Let yₛ, yₜ be two binary vectors with length n, and dist(yₛ,yₜ)=d. If the vector yₛ is randomized with the crossover probability p, and a vector z is received, then

$$Pr \{ dist ( z , {y}_{t} ) < dist ( z , {y}_{s} ) \} \approx {2}^{- d D ( \frac{1}{2} \vert \vert p )} , \\ where$$

$$D ( \frac{1}{2} \vert \vert p ) = - log 2 \sqrt{p ( 1 - p )}$$

is the Kullback-Leibler (KL) divergence between ½ and p.

Because the constant weight code Cᵢ has

$$( \begin{matrix}k \\ i\end{matrix} )$$

codewords, then the probability of event E₁ is

$$Pr \{ {E}_{1} \vert y is randomized \} = {\sum }_{{y}^{′} ∈ {C}_{i} : {y}^{′} \neq y} Pr \{ dist ( z , {y}^{′} ) < dist ( z , y ) \} \leq ( \begin{matrix}k \\ i\end{matrix} ) {2}^{- {m i n}_{{y}^{′} , y ∈ {C}_{i} : {y}^{′} \neq y} dist ( {y}^{′} , y ) D ( \frac{1}{2} \vert \vert p ) } = {2}^{lo g ( \begin{matrix}k \\ i\end{matrix} ) - {d}_{i} D ( \frac{1}{2} \vert \vert p )} = ɛ / 2 ,$$

where dᵢ is the minimum distance of the constant weight code Cᵢ,

$${d}_{i} = \frac{1}{D ( \frac{1}{2} \vert \vert p )} log \frac{2 ( \begin{matrix}k \\ i\end{matrix} )}{ɛ} .$$

Similarly, the probability of event E₂ is

$$Pr \{ {E}_{2} \vert y is randomized \} = {\sum }_{{y}^{′} ∈ {⋃}_{j \neq i} {C}_{j} : {y}^{′} \neq y} Pr \{ dist ( z , {y}^{′} ) < dist ( z , y ) \} \leq ( {2}^{k} - ( \begin{matrix}k \\ i\end{matrix} ) ) {2}^{- {m i n}_{{y}^{′} ∈ {⋃}_{j \neq i} {C}_{j} , y ∈ {C}_{i} : {y}^{′} \neq y} dist ( {y}^{′} , y ) D ( \frac{1}{2} \vert \vert p )} = {2}^{k - \overline{d} D ( \frac{1}{2} \vert \vert p )} = ɛ / 2 , \\ Therefore , \\ {P}_{e} \leq \frac{1}{{2}^{k}} {\sum }_{i = 0}^{k} {\sum }_{y ∈ {C}_{i}} ( ɛ / 2 + ɛ / 2 \} ) = ɛ / 2.$$

Universality of the Codings

Proof

The function ƒᵢ is an decreasing in dᵢ. From the definition of dᵢ, dᵢ decreases as p decreases. So, ƒᵢ is an increasing function in p. Also, d̅ is an increasing function of p. With these observations., it is possible to verify that δ*(p)≧δ*(p′) if p≧p′. As such, we can conclude that the s -admissible weight rate preserving code with respect to the crossover probability p constructed in the above proof is also ε-admissible with respect to any the crossover probability p′≦p.

The concrete construction of constant weight code can be determined if the condition

$$\frac{{( k δ )}^{i δ - {d}_{i} / 2 + 1}}{( i δ ) !} \geq ( \begin{matrix}k \\ i\end{matrix} )$$

is satisfied.

We claim:

1. A method for processing a message, comprising the steps of:
generating, using a set of error correcting codes (ECC), a codeword using a selected ECC for each block of the message, wherein the selected ECC depends on a weight rate of the block, and wherein each codeword satisfies a minimum distance criterion with respect to the codewords of all possible ECCs and all possible weight rates;
modifying explicitly, randomly and independently each symbol of the codeword according to parameters of a channel to obtain a randomized codeword; and
decoding an encoded result of an operation performed on the randomized codeword by an untrusted third party, wherein the steps are performed by a client processor.

2. The method of claim 1, wherein multiple messages are processed, and further comprising:
determining aggregate statistics on the multiple messages.

3. The method of claim 1, wherein multiple messages are processed, and further comprising:
determining an audit on the multiple messages.

4. The method of claim 1, wherein the channel is a hypothetical noisy channel.

5. The method of claim 4, wherein the channel is a binary symmetric channel.

6. The method of claim 1, wherein the modification of the codewords according to the hypothetical channel is accomplished by a cryptographically secure pseudo-random number generator.

7. The method of claim 2, wherein the untrusted third party knows the modification parameters, and the aggregate statistics are exact.

8. The method of claim 1 wherein the ECC codeword exactly preserves the weight rate of the block.

9. The method of claim 1 wherein the codeword approximately preserves the weight rate of the block.

11. The method of claim 1, wherein
the modification parameters are kept secret at the client,
the modification of the codewords according to the hypothetical channel is accomplished by a physical unclonable function.

12. The method of claim 1, wherein the channel is generated by cryptographically secure pseudo random number generator.

13. The method of claim 4, wherein the channel is generated by a physical unclonable function.

14. A system for processing a message, comprising:
a client configured to generate a codeword using a selected error correcting code (ECC) from a set of the ECC for each block of the message, wherein the selected ECC depends on a weight rate of the block, and wherein each codeword satisfies a minimum distance criterion with respect to the codewords of all possible ECCs and all possible weight rates, and modifying explicitly, randomly and independently each symbol of the codeword according to parameters of a channel to obtain a randomized codeword; and
a server configured to process the randomized codeword to produce an encoded result for the client.
